(19) United States
(12) Patent Application Publication
(10) Pub. No.: US 2018/0212127 A1
(43) Pub. Date: Jul. 26, 2018

(54) OPTOELECTRONIC COMPONENT, ASSEMBLY OF OPTOELECTRONIC COMPONENTS AND METHOD OF PRODUCING AN OPTOELECTRONIC COMPONENT

(71) Applicant: OSRAM Opto Semiconductors GmbH, Regensburg (DE)

(72) Inventors: David O'Brien, Bad Abbach (DE); Siegfried Herrmann, Neukirchen (DE)

(73) Assignee: OSRAM Opto Semiconductors GmbH, Regensburg (DE)

(21) Appl. No.: 15/745,835

(22) PCT Filed: Jul. 13, 2016
(86) PCT No.: PCT/EP2016/066676

§ 371 Date: Jan. 18, 2018

(30) Foreign Application Priority Data
Jul. 22, 2015 (DE) 10 2015 111 910.2

(51) Int. Cl. H01L 33/64; H01L 33/48; H01L 33/50; H01L 33/60; H01L 33/62; H01L 25/075

(52) U.S. Cl. CPC H01L 33/644; H01L 33/483; H01L 33/502; H01L 33/60; H01L 33/62; H01L 25/0753; H01L 33/06; H01L 2933/0041; H01L 2933/0058; H01L 2933/0066; H01L 2933/0075; H01L 2933/0083; H01L 2933/0033

(57) ABSTRACT

An optoelectronic component includes a semiconductor chip configured to emit radiation at least via a main radiation surface, a converter element arranged in a beam path of the semiconductor chip, an encapsulating element including a cover element and a side element and forming at least a seal for the converter element against environmental influences, wherein the cover element is arranged above the converter element and the side element, in the cross-section, is arranged laterally to the semiconductor chip and converter element and surrounds the semiconductor chip, the side element and the cover element are in direct contact at least in regions, and the side element includes at least one metal and is in direct contact with the converter element in the lateral direction.

### TECHNICAL FIELD

This disclosure relates to an optoelectronic component and an assembly of optoelectronic components. Furthermore, the disclosure relates to a method of producing an optoelectronic component.

### BACKGROUND

Optoelectronic components often comprise converter elements that can convert radiation emitted by a semiconductor chip into radiation with an altered wavelength, for example. However, such converter elements are often susceptible to humidity, oxygen and/or temperature. Therefore, the converter elements must be protected against external influence and/or the influence of high temperatures.

It could therefore be helpful to provide an optoelectronic component that is stable and an optoelectronic component comprising a converter element protected against environmental influence and/or temperature influence. Furthermore, it could be helpful to provide an assembly of optoelectronic components that is stable and a method of producing a stable optoelectronic component.

### SUMMARY

We provide an optoelectronic component including a semiconductor chip configured to emit radiation at least via a main radiation surface, a converter element arranged in a beam path of the semiconductor chip, an encapsulating element including a cover element and a side element and forming at least a seal for the converter element against environmental influences, wherein the cover element is arranged above the converter element and the side element, in the cross-section, is arranged laterally to the semiconductor chip and converter element and surrounds the semiconductor chip, the side element and the cover element are in direct contact at least in regions, and the side element includes at least one metal and is in direct contact with the converter element in the lateral direction.

We also provide an assembly of the optoelectronic component including a semiconductor chip configured to emit radiation at least via a main radiation surface, a converter element arranged in a beam path of the semiconductor chip, an encapsulating element including a cover element and a side element and forming at least a seal for the converter element against environmental influences, wherein the cover element is arranged above the converter element and the side element, in the cross-section, is arranged laterally to the semiconductor chip and converter element and surrounds the semiconductor chip, the side element and the cover element are in direct contact at least in regions, the side element includes at least one metal and is in direct contact with the converter element in the lateral direction, and neighboring optoelectronic components have a common side element.

We further provide a method of producing the optoelectronic component including a semiconductor chip configured to emit radiation at least via a main radiation surface, a converter element arranged in a beam path of the semiconductor chip, an encapsulating element including a cover element and a side element and forming at least a seal for the converter element against environmental influences, wherein the cover element is arranged above the converter element and the side element, in the cross-section, is arranged laterally to the semiconductor chip and converter element and surrounds the semiconductor chip, the side element and the cover element are in direct contact at least in regions, and the side element includes at least one metal and is in direct contact with the converter element in the lateral direction including: A) providing a cover element of an encapsulating element, B) applying a converter element on to the cover element of the encapsulating element, wherein the converter element includes side surfaces, C) applying at least one semiconductor chip on to the converter element, wherein the semiconductor chip is configured to emit radiation at least via a main radiation surface and includes side surfaces, and D) applying a side element on to the side surfaces of the semiconductor chip and on to the side surfaces of the converter element so that, in the cross-section, the side element is arranged laterally to the semiconductor chip and converter element and directly surrounds at least the semiconductor chip, wherein the side element and the cover element directly contact one another at least in some regions and form a seal for the converter element against environmental influences, and the side element includes at least one metal and is in direct contact with the converter element in the lateral direction.

### BRIEF DESCRIPTION OF THE DRAWINGS

FIGS. 1A and 1B each show a schematic sectional view of an optoelectronic component according to an example.

FIG. 2A shows a schematic side view of an optoelectronic component according to an example.

FIG. 2B shows a top view of the optoelectronic component of FIG. 2A.

FIG. 3 shows a schematic side view of an optoelectronic component according to one example.

FIGS. 4A to 4H show a method of producing an optoelectronic component according to an example.

FIGS. 5A to 5C each show a method of producing an optoelectronic component according to an example.

FIG. 6A shows a schematic side view of an optoelectronic component according to an example.

FIG. 6B shows a plan view of the component of FIG. 6A.

FIGS. 7A to 7F show a method of producing an optoelectronic component according to an example.

FIGS. 8A to 8C show a top view of an assembly of an optoelectronic component according to an example.

FIGS. 9A and 9B each show a schematic side view of an optoelectronic component according to an example.

### LIST OF REFERENCE CHARACTERS

100 Optoelectronic component
1 Semiconductor chip
12 Side surfaces of semiconductor chip
11 Main radiation surface
2 Converter element
21 Side surfaces of converter element
3 Encapsulating element
31 Cover element
32 Side element
4 Carrier
5 Radiation of the semiconductor chip
6 Seed layer
7 Adhesive layer or further layer
8a Rear-side contact
8b Rear-side contact
9 Insulation
10a n-contact
10b p-contact
13 Mask
14 Radiation, in particular UV radiation
15 Photoresist
16 Singulating
101 n-type semiconductor layer
102 Active layer
103 p-type semiconductor layer
17 Insulating material
18 Sub-mount/carrier
19 Combo mirror

### DETAILED DESCRIPTION

The optoelectronic component may comprise a semiconductor chip. The semiconductor chip is configured to emit radiation at least via a main radiation surface of the semiconductor chip. The optoelectronic component comprises a converter element. The converter element is arranged in the beam path of the semiconductor chip. In particular, the converter element is susceptible to environmental influence and/or temperature influence. The optoelectronic component comprises an encapsulating element. The encapsulating element comprises a cover element and a side element. The encapsulating element forms at least a seal against environmental influence for the converter element. In addition, the encapsulating element can protect at least the converter element against temperatures, in particular temperatures exceeding 80° C. so that degradation of the converter element is prevented. The cover element is arranged above the converter element. In the cross-section, the side element is arranged laterally to the semiconductor chip and the converter element.

The side element in particular directly surrounds the semiconductor chip. The side element and the cover element contact one another at least in some regions. In particular, the side element and the cover element contact one another directly at least in some regions. The side element comprises at least one metal. Alternatively, or in addition, the side element is in direct contact with the converter element in the lateral direction.

The component may comprise a semiconductor chip. The semiconductor chip includes a semiconductor layer sequence. The semiconductor layer sequence of the semiconductor chip is preferably based on a III-V semiconductor compound material. The semiconductor material is preferably a nitride semiconductor compound material such as AlₙInₗ₋ₙ₋ₘGaₘN, or also a phosphide semiconductor compound material such as AlₙInₗ-n-m_{Ga}m_{P}, with 0≤n<1, 0<m≤1 and n+m≤1. The semiconductor material can also be AlₓGaₗ₋ₓAs, with 0≤x≤1. The semiconductor layer sequence can comprise dopants as well as additional constituents. However, for the sake of simplicity, only the essential components of the crystal lattice of the semiconductor layer sequence, namely Al, As, Ga, In, N or P are indicated, even if they can partially be substituted or added with small amounts of further substances.

The semiconductor layer sequence includes an active layer having at least one p-n junction and/or having multiple quantum well layers. Electromagnetic radiation is generated in the active layer during operation of the semiconductor chip. Thus, the semiconductor chip is configured to emit radiation. In particular, emission of radiation is effected via the main radiation surface of the semiconductor chip. The main radiation surface is in particular oriented perpendicular to a growth direction of the semiconductor layer sequence of the optoelectronic component. A wavelength of the radiation or the wavelength maximum of the radiation is preferably in the ultraviolet and/or visible and/or infrared spectral range, in particular at wavelengths 420 to 800 nm, e.g., 440 to 480 nm.

The semiconductor chip may be a light-emitting diode, LED for short. In this case, the semiconductor chip is preferably configured to emit blue light, green light, red light or white light.

The component may comprise a converter element. The converter element is arranged in the beam path of the semiconductor chip. In particular, the converter element is arranged in direct mechanical and/or electric and/or thermal contact with the semiconductor chip. In particular, the converter element is arranged directly on the main radiation surface of the semiconductor chip.

The converter element can alternatively also be spaced from the main radiation surface of the semiconductor chip. For example, the converter element and the main radiation surface can have further layers arranged between them, e.g., an adhesive layer.

In this case, “directly bordering” or “directly” can mean an indirect, electric, mechanic and/or thermal contact of one element to another element. The side element and the converter element can have further elements present between them, e.g., encapsulations, intermediate layers or an air gap.

Alternatively, “directly bordering” or “directly” can mean the direct electric, mechanic and/or thermal contact of one element to another element. In this case, both elements at least in regions do not have other elements arranged between them.

The converter element may be susceptible to environmental influence. In addition, the converter element can be susceptible to temperatures, in particular high temperatures such as temperatures of at least 80° C., e.g., 95° C. The high temperatures can be generated during operation of the optoelectronic component, for example. Environmental influence particularly means a humid atmosphere here, e.g., an atmosphere of water, oxygen and/or hydrogen sulfide. In particular, the converter element degrades upon contact with the environmental influence and/or high temperatures. Therefore, in particular an encapsulating element can be used to prevent degradation. The encapsulating element can form a seal against environmental influence. In addition, the encapsulating element can dissipate at least the heat or the high temperatures generated inside the converter element. An increase in temperature inside the converter element can lead to a radiation-free relaxation and a Stokes shift. The encapsulating element is in particular configured to dissipate heat generated in the converter element and thus to prevent thermal quenching and/or thermal degradation of the converter material, in particular of the quantum dots.

The converter element may comprise or consist of quantum dots as converter materials. As an alternative, the converter element can comprise or consist of converter materials such as YAG-phosphors, garnets, orthosilicates or calsines. The mentioned converter materials are susceptible to oxygen, humidity and/or temperature. Compared to conventional phosphor materials, converter materials comprising quantum dots come with the advantage of having a narrower spectral bandwidth. Furthermore, the wavelength maximum can be adjusted and altered more easily.

Quantum dot refers to a nanoscopic material structure here. In particular, the nanoscopic material structure can comprise or consist of semiconductor materials such as InGaAs, CdSe or GaInP/InP. The quantum dots can have different sizes, for example.

The converter element can comprise a matrix material, e.g., silicone-based and/or epoxy-based polymers and/or acrylates and/or photoresists. The converter materials such as quantum dots can be distributed within the matrix material in a homogenous manner. As an alternative, the converter materials such as quantum dots can have a concentration gradient in the matrix materials. The content of converter materials in the matrix material can be at least 60 wt.-%, e.g., 70 wt.-%, 80 wt.-%, 90 wt.-% or 96 wt.-%.

The converter element is in particular configured to absorb radiation emitted by the semiconductor chip and convert the radiation into radiation, in particular of a different wavelength. The converter element can convert the radiation emitted by the semiconductor chip completely. As an alternative, the converter element can at least partially convert the radiation emitted by the semiconductor chip, with a portion of the radiation emitted by the semiconductor chip passing through the converter element without being converted. This results in a mixed radiation including the radiation emitted by the semiconductor chip and the radiation converted by the converter element.

The quantum dots may have different sizes. The size can be 2 nm to 12 nm. This allows the spectral range emitted by the quantum dot to be adjusted individually. In particular, converter materials having quantum dots can be used for a so-called Solid State Lighting (SSL) and display backlighting, for example.

The converter element may be formed as a layer with a layer thickness of 100 nm to 1,500 nm.

The component may comprise an encapsulating element. The encapsulating element comprises or consists of a cover element and a side element. The encapsulating element is configured to protect at least the converter element against environmental influences and/or thermal influence.

The encapsulating element may encapsulate at least the converter element and the semiconductor chip. In other words, the converter element is not encapsulated separately, but encapsulated inside the component together with the semiconductor chip and the converter element. In particular, the encapsulating element is hermetically sealed, i.e., diffusion-tight against environmental influences such as oxygen, water and/or hydrogen sulfide.

The cover element may be arranged in the beam path of the semiconductor element. The cover element is arranged above the converter element. The cover element can be arranged in direct mechanical contact to the converter element, i.e., in direct electric and/or mechanic and/or thermal contact. As an alternative, the cover element can be arranged in indirect contact above the converter element. Further layers or elements such as an adhesive layer can be arranged between the cover element and the converter element.

A layer being arranged or applied “on to” or “above” another layer can mean that one layer or one element is arranged in direct mechanical and/or electric and/or thermal contact on to the other layer or the other element. Furthermore, it can also mean that one layer or one element is arranged indirectly on or above the other layer or the other element. Further layers and/or elements can be arranged between one layer and the other layer or between one element and the other element, respectively.

In particular, the converter element comprises a main radiation side. The main radiation side of the converter element is oriented particularly perpendicular to the growth direction of the semiconductor layer sequence of the semiconductor chip. In particular, the cover element covers the main radiation side of the converter element directly and/or in a form-fit manner.

The cover element may be configured in the form of a layer, a board, a foil or a laminate. The cover element can be made of glass, quartz, plastic and/or silicon dioxide. In particular, the cover element can comprise or consist of glass.

The cover element may be transmissive at least for the radiation emitted by the semiconductor chip and/or for the radiation emitted by the converter element. In particular, the cover element is of transparent design. “Transparent” refers to a layer that is transmissive to visible light. In this case, the transparent layer can be clear(-sighted) or at least partially light-scattering and/or partially light-absorbing such that the transparent layer can also be diffuse or opaquely translucent. Particularly preferably, a layer or an element referred to as transparent here is transmissive to light as far as possible such that in particular absorption of radiation generated during operation of the optoelectronic component is as low as possible.

The cover element may comprise a diffusor or other optically-active structures. In particular, the diffusor or the other optically-active structures are configured to out-couple the radiation generated inside the component. For example, a roughened glass (frosted glass) can be used as the cover element, the roughness of which is similar or smaller than the wavelength of the radiation to be outcoupled. It is also possible to embed scattering particles into the glass or form the cover element of glass in the shape of a lens, e.g., a Fresnel lens or provide the glass with a periodic structure (“grating”).

The component may comprise a side element. In the cross-section, the side element is arranged laterally to the semiconductor chip. As an alternative or in addition, the side element is arranged laterally to the converter element, in a cross-section view. In particular, the converter element and the semiconductor chip are arranged one above the other such that the side element extends both on the side surfaces of the semiconductor chip and on the side surfaces of the converter element. The side element can be arranged directly or indirectly on the semiconductor chip and/or the converter element. In indirect contact, in particular a seed layer can be arranged between the side element and the side surfaces of the semiconductor chip and/or of the converter element.

The side element may surround the semiconductor chip. In particular, the side element directly surrounds the semiconductor chip. In other words, the side element covers the semiconductor chip such that at least a thermal contact is provided between semiconductor chip and side element. Alternatively, or in addition, a direct electric and/or mechanical contact is provided between the semiconductor chip and the side element. The side element covers the semiconductor element in particular in a form-fit manner, namely completely covers all side surfaces of the semiconductor chip.

The side element may comprise at least one metal, in particular a galvanic metal. In particular, the side element consists of a metal, which is a galvanic metal, in particular. The metal can be selected from a group including copper, nickel, iron, gold and silver. The side element preferably includes or consists of copper or nickel. Copper has a high thermal conductivity of approximately 390 W/(m·K), compared, e.g., to sapphire, 25 W/(m·K) so that copper can readily dissipate heat generated in the converter element in an excellent manner. This allows a side element formed of copper to be used as an additional heat path to dissipate the heat generated in the converter element.

The side element may comprise or consist of at least one galvanic metal. The cover element comprises or consists of a material different from the side element, e.g., glass. The cover element is transparent to the radiation emitted by the semiconductor chip. As an alternative or in addition, the side element has a cross-sectional thickness of more than 20 μm or more than 60 μm, in particular 80 μm to 200 μm, e.g., 100 μm.

The side element and the cover element may directly contact one another at least in some regions. The side element and the cover element form an inverse “U” viewed in the cross-section and from the side. The side element is additionally in direct contact with the side surfaces of the semiconductor chip so that the converter element is surrounded by the semiconductor chip, the side element and the cover element. As a result, a seal against external influence for at least the converter element is present.

The side element may be formed as an electric connection contact of the semiconductor chip. The semiconductor chip in particular comprises or consists of at least a p-type semiconductor layer, an active layer and at least one n-type semiconductor layer. The p-type semiconductor layer and the n-type semiconductor layer are each electrically-contacted to at least one electric connection contact. In other words, the side element forms an electrical connection contact of the semiconductor layer sequence. The side element forms an electrical connection contact for the at least one p-type semiconductor layer and/or the at least one n-type semiconductor layer. Another electric connection for, e.g., the semiconductor layer can therefore be dispensed with. This saves costs and material.

The side element may be arranged on a carrier. The carrier can be a printed circuit board (PCB), a lead frame, a ceramic-based carrier or a metal, for example. In particular, the converter element and/or the side element is arranged at least in direct thermal contact to the carrier. The side element in particular serves as a heat sink for the converter element and/or the semiconductor chip. In other words, heat generated during operation of the converter element can readily be dissipated via the side element. This can prevent a thermal degradation of the converter element. The side element thus provides an additional heat path.

In particular, the side element is in direct thermal and/or mechanical contact with both the converter element and/or the semiconductor chip, and the carrier. This allows heat generated in the converter element to be readily be dissipated towards the carrier via the side element. In addition, the side element contributes to a mechanical stabilization of the semiconductor chip and of the converter element.

The side element may be of reflective design. In particular, the side element is arranged on the side surfaces of the semiconductor chip. This allows the radiation emitted by the semiconductor chip to be reflected by the side element, and therefore increase to the out-coupling efficiency of the radiation emitted by the semiconductor chip.

Alternatively or in addition, the side element of reflective design is arranged on the side surfaces of the converter element. This allows increasing the radiation emerging from the converter element from the side surfaces thereof to be reflected, and thus increasing the out-coupling efficiency in the direction towards the main radiation direction, i.e., in the direction perpendicular to the main radiation side or main radiation surface.

The semiconductor chip and the converter element may each comprise side surfaces directly covered by the side element in a form-fit manner. In other words, the side element in particular takes the shape of the side surfaces of the converter element and/or of the semiconductor chip.

The side element covers the side surfaces of the converter element in particular completely. As an alternative or in addition, the side element completely covers the side surfaces of the semiconductor chip or at least by 80%, or more than 90%. In particular, at a coverage of at least 80%, the side surfaces of the semiconductor chips remain uncovered in the region of a carrier.

The component may comprise a seed layer. In particular, the side surfaces of the converter element are covered by the seed layer, in particular directly covered. In other words, the seed layer is directly arranged on the side surfaces, i.e., in direct mechanical, electrical and/or thermal contact to the converter element. The seed layer may cover the side surfaces of the semiconductor chip and/or of the converter element directly in a form-fit manner. The seed layer can additionally be arranged on the side surfaces of the semiconductor chip. In particular, the seed layer directly covers the side surfaces of the semiconductor chip at least in regions. In other words, the side surfaces of the semiconductor chip are not completely covered by the seed layer. This can be generated by the so-called “mushroom process” during operation. In particular, the side surfaces remain free of the seed layer in the region of the carrier. Alternatively, or in addition, the side element is arranged laterally downstream of the seed layer. In particular, side element and seed layer are in direct thermal contact to one another.

The seed layer may comprise a metal. In particular, this is a conductive, sputtered metal layer. The metal is selected from the group including Ag, Al, Cu and combinations thereof. The metal is preferably Ag or Al. The seed layer is in particular configured to dissipate heat generated by the converter element and/or the semiconductor chip towards the side surface. In addition, the side element can be arranged on a carrier such that heat can be dissipated both via the seed layer and the side element and the carrier in an excellent manner.

The seed layer may be of reflective design. “Reflective” means that at least 90% or 95% of the radiation impinging the seed layer is reflected. In particular, silver can be used as the seed layer. Silver has a high reflectivity and can therefore readily reflect radiation generated in the converter element and/or in the semiconductor chip and thereby increase out-coupling efficiency.

The cover element and the side element may comprise different materials. In particular, the side element is metallic and/or the cover element is non-metallic. This combines different materials of cover element and side element. In particular, cover element and side element form an excellent seal or hermetic encapsulation at least for the converter element. The side element additionally forms a mechanical stabilization for the semiconductor chip and/or the converter element.

The side element may thermally-connect the carrier and the converter element with one another. This allows an excellent dissipation of heat generated in the converter element.

We found that an excellent seal can be produced at least for the converter element by the use of an encapsulating element comprising a cover element and a side element. This allows the converter element to be protected against environmental influence, in particular humidity, sour gas and/or hydrogen, and therefore prevent degradation thereof. Furthermore, forming the metal side element can produce a simple dissipation of the heat generated in the converter element. Therefore, the encapsulation does not only serve as a seal against environmental influence, but also to dissipate heat. Furthermore, the encapsulating element can be a mirror element, in particular if the side element is of reflective design. Radiation emitted by the side surfaces of the semiconductor chip and the converter element can be reflected additionally, and thus the outcoupling efficiency can be increased. In other words, both the thermal properties and the optical properties as well as the protection of the component against external influence can be improved by the encapsulating element.

We also provide an assembly of optoelectronic components. The assembly of optoelectronic components includes at least one optoelectronic component described above. In other words, all features disclosed for the optoelectronic component are also disclosed for the assembly of optoelectronic components and vice versa.

The assembly of optoelectronic components may comprise at least two optoelectronic components. The optoelectronic components can either be identical in construction or have a different structure. In particular, neighboring optoelectronic components have a common side element. The optoelectronic components can be arranged in the assembly as well as in a so-called wafer assembly. The optoelectronic components are then arranged on the wafer in particular in the type of a matrix. Due to the common side element, the assembly can be mechanically stabilized. Furthermore, the side element can be used as a heat sink for neighboring components. In particular, the side element can readily dissipate the heat generated in the semiconductor chip and/or the converter element.

At least neighboring optoelectronic components may be connected in series.

We further provide a method of producing an optoelectronic component. The method of producing the optoelectronic component preferably produces the optoelectronic component and/or the assembly. In other words, all features disclosed for the optoelectronic component or the assembly are also disclosed for the method of producing an optoelectronic component and vice versa.

The method of producing an optoelectronic component may comprise the following method steps:
A) Providing a cover element of an encapsulating element,
B) Applying a converter element on to the cover element of the encapsulating element, wherein the converter element comprises side surfaces,
C) Applying at least one semiconductor chip on to the converter element, wherein the semiconductor chip is configured to emit radiation at least via a main radiation surface. The converter element comprises side surfaces and
D) Applying a side element on to the side surfaces of the semiconductor chip and the side surfaces of the converter element such that in the cross-section, the side element is arranged laterally to the semiconductor chip and laterally to the converter element and surrounds at least the semiconductor chip. In particular, the side element directly surrounds at least the semiconductor chip, that is in direct electrical, mechanical and/or thermal contact. In particular, the side element and the cover element are in direct contact with one another at least in some regions, and form a seal against environmental influence for the converter element. As an alternative or in addition, the cover element and the side element form a seal for the converter element against environmental influence and/or high temperatures. The side element comprises at least one metal. In addition, the side element can be in direct contact with the converter element in the lateral direction.

In other words, the seal of the converter element is produced already during production of the component or the assembly, and not in a subsequent process, e.g., when the component is introduced in a housing and potted with a sealing material. This allows the component to be produced more compactly and cost-effectively. In addition, thermomechanical stress of the component, e.g., on the interfaces, can be reduced compared to a component that is sealed after production.

The side element may be produced galvanically in step D).

A seed layer may be applied completely on to the side surfaces of the converter element and at least in some regions on to the side surfaces of the semiconductor chip, prior to step D). In particular, the seed layer is of reflective design. In particular, the seed layer is silver. As an alternative or in addition, the seed layer is an alloy of silver and copper. This allows to increase both reflectivity and thermal conductivity at the same time.

Further advantages and developments result from the examples described in the following in conjunction with the Figures.

In the examples and the figures, like, similar or equivalent elements can be denoted with the same reference characters, respectively. The illustrated elements and the size ratios are not to be considered as being true to scale. Rather, individual elements such as layers, components, structural elements and regions can be illustrated in an exaggerated size for the purpose of a better illustration and/or a better understanding.

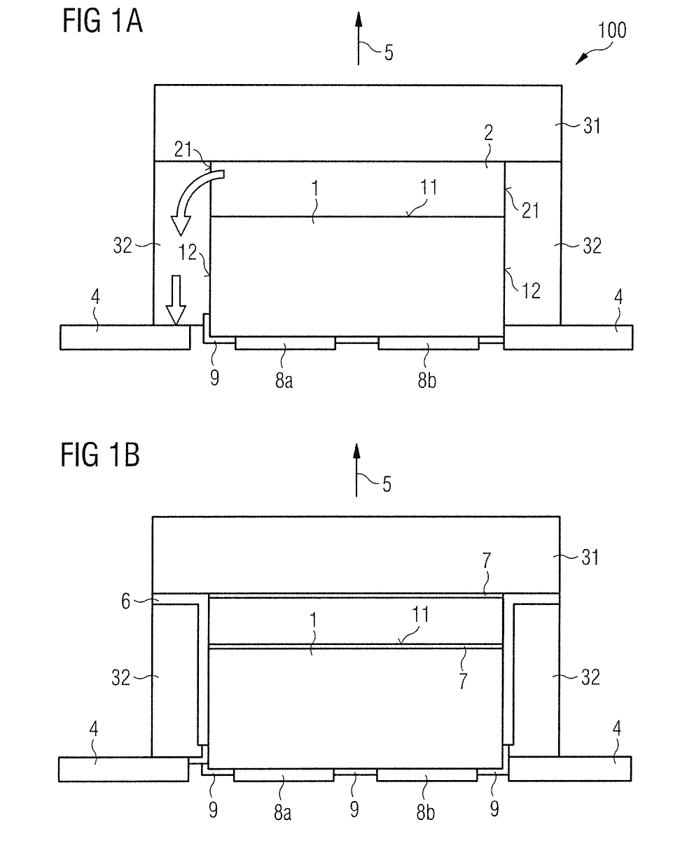

FIG. 1A shows a schematic side view of an optoelectronic component according to one example. The optoelectronic component 100 comprises a semiconductor chip 1. The semi-conductor chip 1 can comprise a semiconductor layer sequence made of InGaN, for example.

The semiconductor chip 1 is in particular configured to emit radiation of the blue spectral range. The semiconductor chip 1 can be formed as a so-called Flip Chip. In other words, the semiconductor chip 1 comprises rear-side contacts 8a and 8b on the side facing away from the main radiation surface 11. In particular, the main radiation surface 11 is oriented perpendicular to the growth direction of the semiconductor layer sequence of the semiconductor chip 1. The rear-side contacts 8a, 8b can be electrically-insulated from one another by an insulation 9 such that a short-circuit is prevented. A converter element 2 including quantum dots, for example, can be arranged downstream on the main radiation surface 11 of the semiconductor chip 1.

In particular, the converter element 2 is arranged directly on the main radiation surface 11. The semiconductor chip 1 comprises side surfaces 12. The converter element 2 comprises side surfaces 21. In particular, the converter element 2 is arranged on the main radiation surface 11 of the semiconductor chip 1 such that, in the cross section, the side surfaces 21 of the converter element form an elongation of the side surfaces 12 of the semiconductor chip 1. The converter element 2 is configured to at least partially convert the radiation emitted by the semiconductor chip 1 into radiation of an altered, in particular longer wavelength.

The converter element 2 can have a cover element 31, for example, of glass or a coated film arranged downstream of it. In particular, the side surfaces of the cover element protrude beyond the side surfaces 21 of the converter element 2 and/or the side surfaces 12 of the semiconductor chip 1 in a side view or in the cross-section.

A side element 32 is arranged laterally to the semiconductor chip 1 and/or the converter element 2. In particular, the side element 32 completely surrounds the converter element 2 and/or the semiconductor chip 1. In other words, the side element 32 at least partially or completely covers all side surfaces of the semiconductor chip 1 and/or all side surfaces 21 of the converter element 2. The side element 32 has a direct contact to the cover element 31. In particular, strong adhesive forces are active between the side element 32 and the cover element 31. The cover element 31 and the side element 32 have the shape of an inverse “U” in a cross-sectional view.

In particular, the cover element 31 and the side element 32 form an encapsulating element 3. The encapsulating element 3 forms a seal against environmental influence and/or high temperatures for the converter element 2. The side element 32 in particular comprises a high-thermally conductive metal, e.g., copper. Therefore, the heat generated by the converter element 2 can readily be dissipated via the side element 32 (indicated by the arrows). Alternatively or in addition, the component 100 can comprise a carrier 4. The carrier 4 can be a metal lead frame, for example. This allows the heat generated by the converter element 2 to be easily dissipated via the side element 32 and via the carrier 4.

The side element 32 can be formed as a layer or as a board. In particular, the side element 32 has a layer thickness of >50 μm in the cross-section. Alternatively, the side surfaces 21 of the converter element 2 can be in direct contact to the side element 32.

In particular, the side element 32 forms a heat sink together with the carrier 4 to dissipate heat generated in the converter element 2 and/or in the semiconductor chip 1. This can prevent degradation of the converter element. In addition, the semiconductor chip 1 and the converter element 2 can be mechanically stabilized.

FIG. 1B shows a schematic side view of an optoelectronic component according to an example. The component 100 of FIG. 1B differs from the component 100 of FIG. 1A in that a further layer, in particular an adhesive layer 7, is arranged between the semiconductor chip 1 and the converter element 2. Furthermore, another layer 7, e.g., an adhesive layer, can be arranged between the converter element 2 and the cover element 31.

Alternatively or in addition, a seed layer 6 can be arranged between the side element 32 and the side surfaces 12 of the semiconductor chip 1 and/or the side surfaces 21 of the converter element 2. The seed layer 6 can additionally be formed between the side element 32 and the cover element 31. In particular, the seed layer 6 is formed as an inverse “L” in the cross-section. In particular, the seed layer 6 is thermally-conductive.

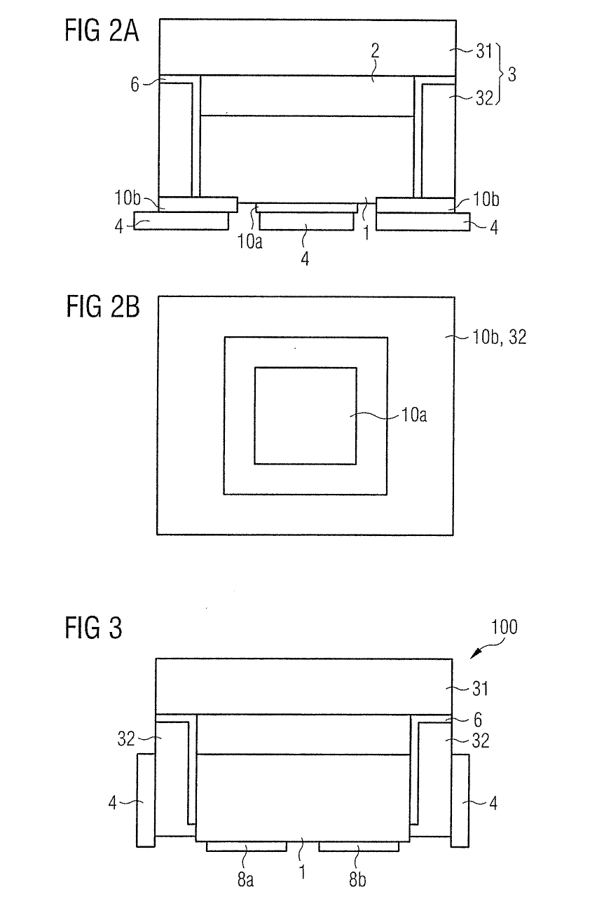

FIG. 2A shows a schematic side view of a component according to an example. The component 100 of FIG. 2A differs from the component of FIG. 1B in that the component comprises electrical connection points 10a and 10b. The electrical connection points 10a are in particular a n-contact and a p-contact. The side element 32 and the p-contact 10b are arranged in thermal contact to one another. The contact 10b is in particular arranged between the carrier 4 and the side element 32. A simple heat dissipation via the side element 32 and the p-contact 10b to the carrier 4 can be effected. The n-contact 10a is arranged below the semiconductor chip, in particular centrally in relation to the semiconductor chip 1 in a cross-section view.

FIG. 2B shows the top view of the optoelectronic component of FIG. 2A. It can be discerned in FIG. 2B that the electrical connection point 10b surrounds the semiconductor chip 1. The electrical connection point 10b, in particular the p-contact, particularly serves for electrically-contacting and as a thermal heat sink here.

The side element 32 surrounds the semiconductor chip 1. The side element 32 in particular surrounds all side surfaces 12 of the semiconductor chip 1 in a form-fit manner.

FIG. 3 shows a schematic side view of an optoelectronic component 100 according to an embodiment. The component 100 of FIG. 3 differs from the component of FIG. 2A in that the carrier 4 of the component of FIG. 3A is arranged laterally to the semiconductor chip 1 and the side element 32. In other words, the side element 32 can be arranged on the carrier 4 (as shown in FIG. 2A), or the carrier 4 can be arranged laterally, i.e., on the side surfaces of the side element 32.

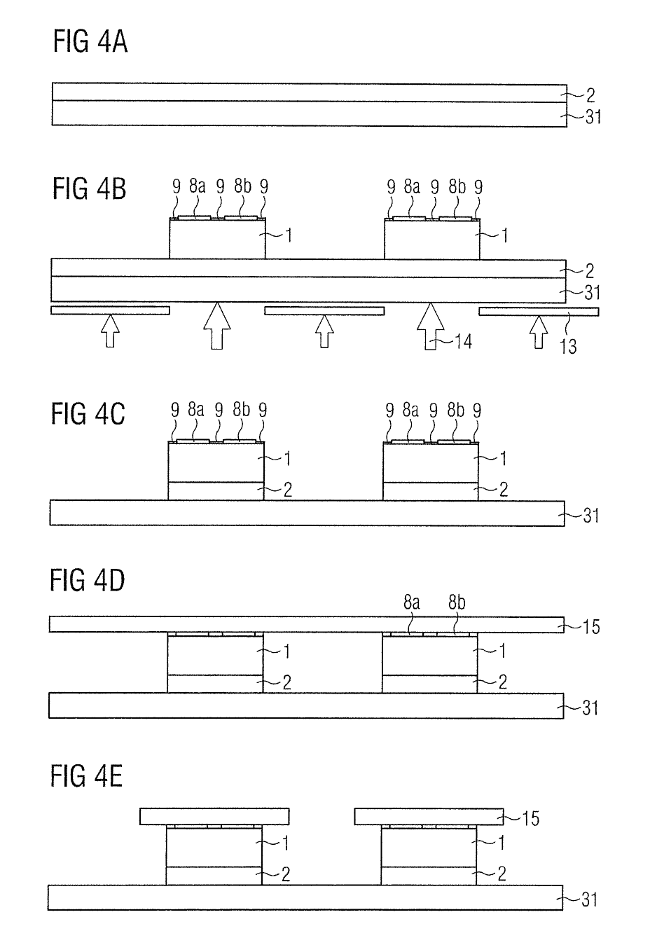

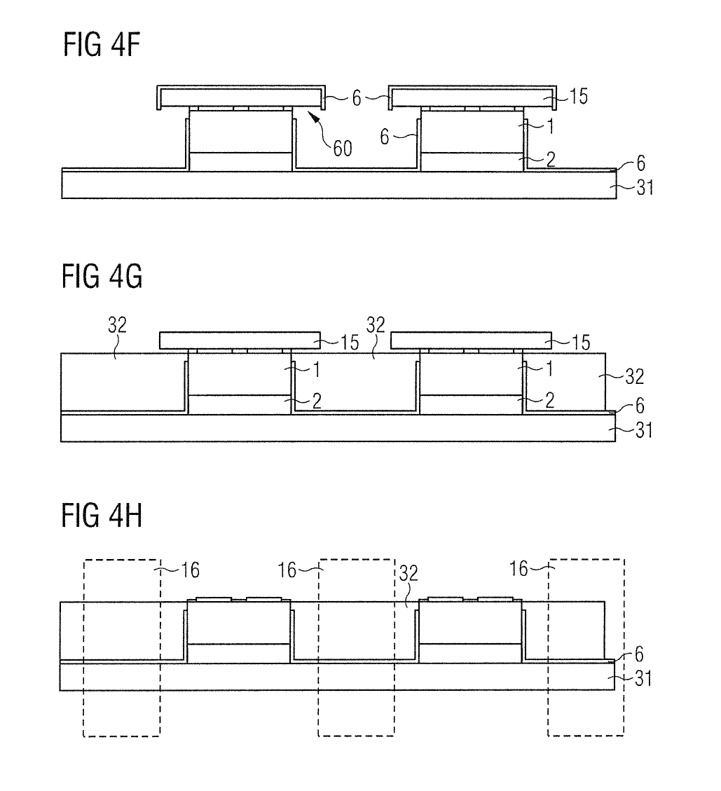

FIGS. 4A to 4H show a method of producing an optoelectronic semiconductor component 100 according to one example. In particular, the method steps of FIGS. 4A and 4B are effected in an inert atmosphere.

FIG. 4A shows the provision of a cover element 31, which in particular is a glass or a sealing film. The converter element 2 is applied on to this cover element 31. In particular, the converter element 2 includes a matrix material. The matrix material is in particular a negative photoresist material. The matrix material is an Ormocer, particularly an Ormoclear. The matrix material is in particular UV-curable. In particular converter materials, e.g., quantum dots, are dispersed in this matrix material. This converter element 2 is applied on to the cover element 31 (FIG. 4A).

Subsequently, at least one semiconductor chip 1 is applied. FIG. 4B shows application of two semiconductor chips 1. In particular, more than two semiconductor chips 1 can be applied just as well. The semiconductor chips 1 are directly applied on to the converter element 2. Subsequently, masks 13 are applied on to the side of the cover element 31 facing away from the semiconductor chip 1.

Subsequently, curing of the matrix material of the converter element 2 is effected. Curing is effected by photolithography 14, in particular with ultraviolet radiation. As a result, the matrix material is cured selectively and the respective semiconductor chips 1 and converter elements 2 are fixed.

The uncured matrix material of the converter element 2 can subsequently be removed (FIG. 4C). This produces a converter element 2 between the semiconductor chip 1 and the cover element 31. Subsequently, a seal can be applied. The seal can be applied by atomic layer deposition, ALD for short. This sealing layer can be temporarily. Inorganic oxides, e.g., alumina, can be applied temporarily. As an alternative, processing could also be effected in an inert atmosphere.

Subsequently, a photoresist layer 15 can be applied as shown in FIG. 4D. In particular, the photoresist layer 15 is applied on to the side of the rear-side contacts 8a, 8b. This can be effected by a so-called alpha cube process. This allows protecting the rear-side contacts 8a, 8b.

FIG. 4E shows that the photoresist layer 15 can be used as a mask at the same time. The side surfaces of the mask project beyond the side surfaces 12, 21 of the semiconductor chip 1 and/or of the converter element 2. This forms an arrangement of a component that looks like a mushroom. This is why this process is also referred to as mushroom process.

FIG. 4F optionally shows application of a seed layer 6. The seed layer 6 is applied on to the surface of the cover element 31 and on to the side surface 21 of the converter element 2 and at least in sections on to the side surfaces 12 of the semiconductor chip 1. The seed layer 6 can be applied galvanically or by sputtering. As the photoresist layer has overhanging edges, the side surfaces 12 of the semiconductor chip 1 are not completely covered with the seed layer 6. The side surfaces 12 of the semiconductor chip 1, in particular directly below 60 of the photoresist layer 5 are free of the seed layer 6. The seed layer 6 in particular includes a thermally-conductive metal or a conductive material such as copper or another metal. The seed layer 6 in particular has a layer thickness of <100 nm.

FIG. 4G shows application of the side element 32. In particular, application of the side element 32 is effected galvanically. The side element 32 can be copper or nickel, for example. Alternatively, also other galvanic elements or alloys such as, e.g., iron, zinc or other precious metals such as gold or copper are suitable. The side element 32 connects with the seed layer 6 at least electrically.

Subsequently, the photoresist layer 15 can be removed and the neighboring components can be singulated 16 (FIG. 4H). This results in a component 100, for example, of FIGS. 1A or 1B.

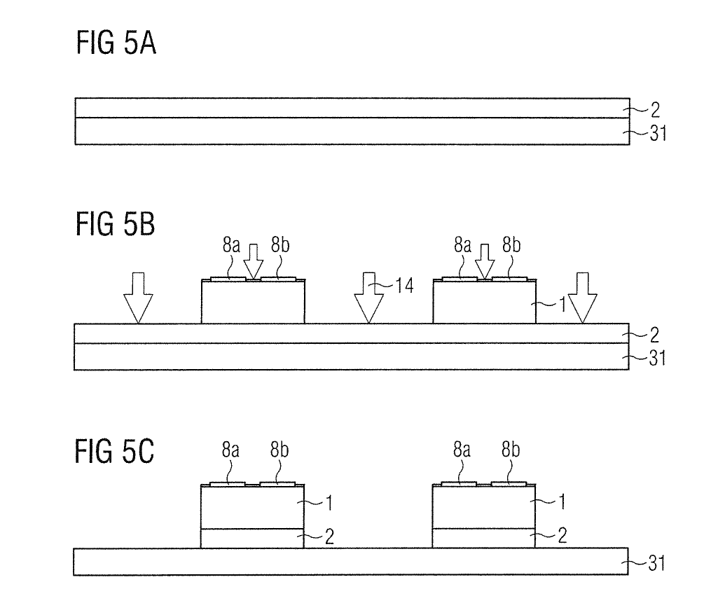

FIGS. 5A and 5B show a method of producing an optoelectronic component. The method steps of FIGS. 5A and 5B in particular are effected in an inert atmosphere. FIG. 5A shows the provision of a cover element 31. A converter element 2 is applied on to this cover element 31. The converter element 2 comprises a matrix material including a positive resist material. In particular, a converter material such as quantum dots is dispersed in the positive resist material.

The method of FIGS. 5A to 5C differs from the method of FIGS. 4A to 4C in that in the method of FIGS. 5A to 5C, a positive resist material is used, whereas in FIGS. 4A to 4C, a negative resist material is used.

FIG. 5B shows application of the semiconductor chips 1. The semiconductor chips 1 are applied on to the converter element 2. Due to the fact that a positive resist material is concerned in the converter element 2, the converter element 2 is irradiated from the side of the semiconductor chip by photolithography. Irradiation 14 is in particular effected by UV radiation. In other words, the semiconductor chip 1 serves a mask here, whereas in the method of FIGS. 4A to 4H, an additional mask 13 must be applied. The photoresist material is cured in the converter element 2 by the photolithographic processes. Subsequently, as shown in FIG. 5C, the excess converter element 2 can be removed. In addition, an additional converter layer can be applied by ALD, which is temporary.

The steps of FIGS. 4D to 4H can be effected in analogy after the step of FIG. 5C.

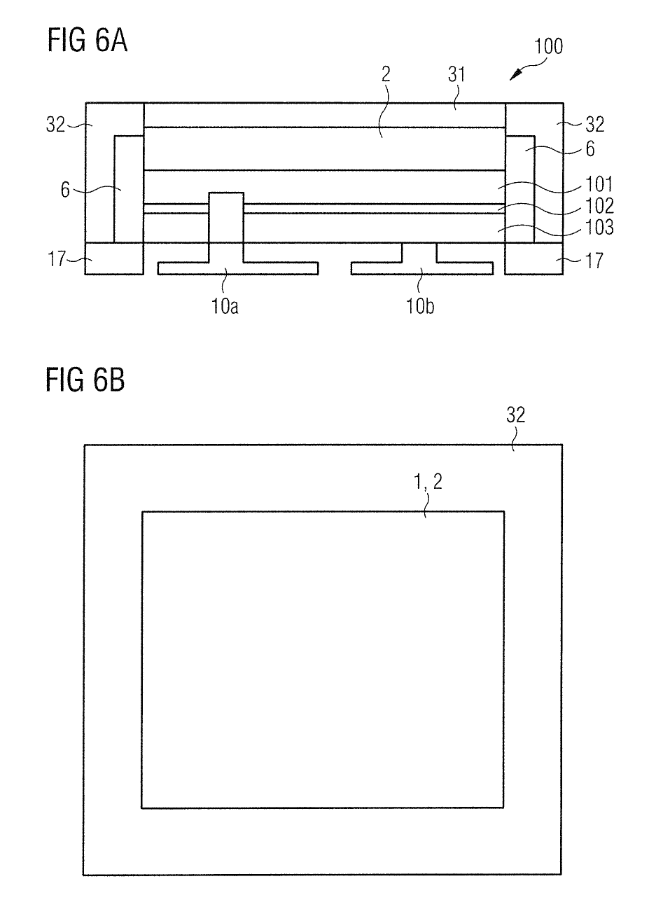

FIG. 6A shows a schematic side view of an optoelectronic component 100 according to one example. The optoelectronic component 100 shows a semiconductor layer sequence 101 to 103. The layer 101 is at least an n-type semiconductor layer. The layer 102 is the active layer and the layer 103 is at least a p-type semiconductor layer. The n-type semiconductor layer 101 is electrically contacted by an n-contact 10a. The layer 103 is electrically-contacted by a p-contact 10b. The component 100 further comprises a cover element 31 and a converter element 2 arranged between the semiconductor layer sequence 101 to 103 and the cover element 31. The side element 32 is arranged laterally to the semiconductor chip 1 including the semiconductor layer sequence 101 to 103. A seed layer 6 is arranged between the side element 32 and the semiconductor chip 1. The component 100 further comprises an insulating material 17. In particular, the seed layer 6 is formed as a mirror layer. In other words, the seed layer 6 reflects the radiation emitted by the semiconductor chip 1.

FIG. 6B shows a top view of the component of FIG. 6A. It can be discerned in FIG. 6B that the side element 32 covers the side surfaces 12 of the semiconductor chip and in particular the side surfaces 21 of the converter element 2 on all sides and in a form-fit manner.

The side element 32, which in particular a galvanic board, is configured for the mechanical stabilization. The side element 32 can also serve as a heat sink for the converter element 2.

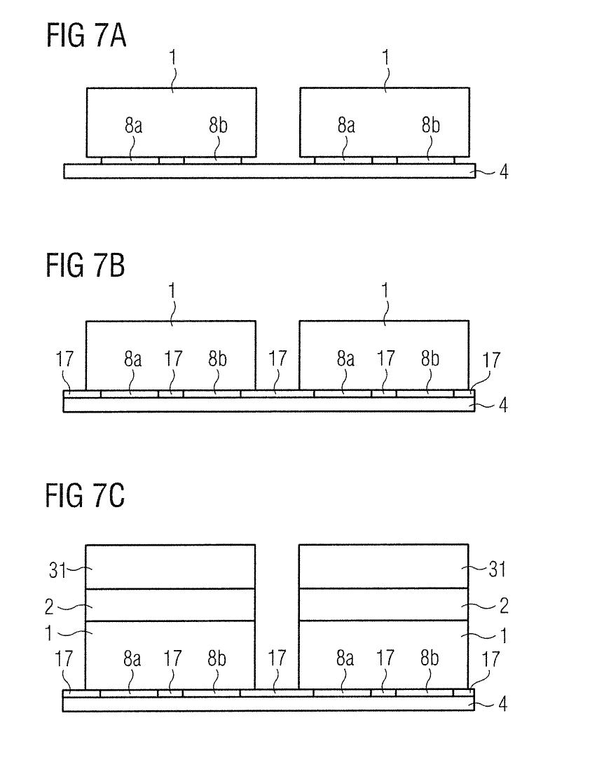

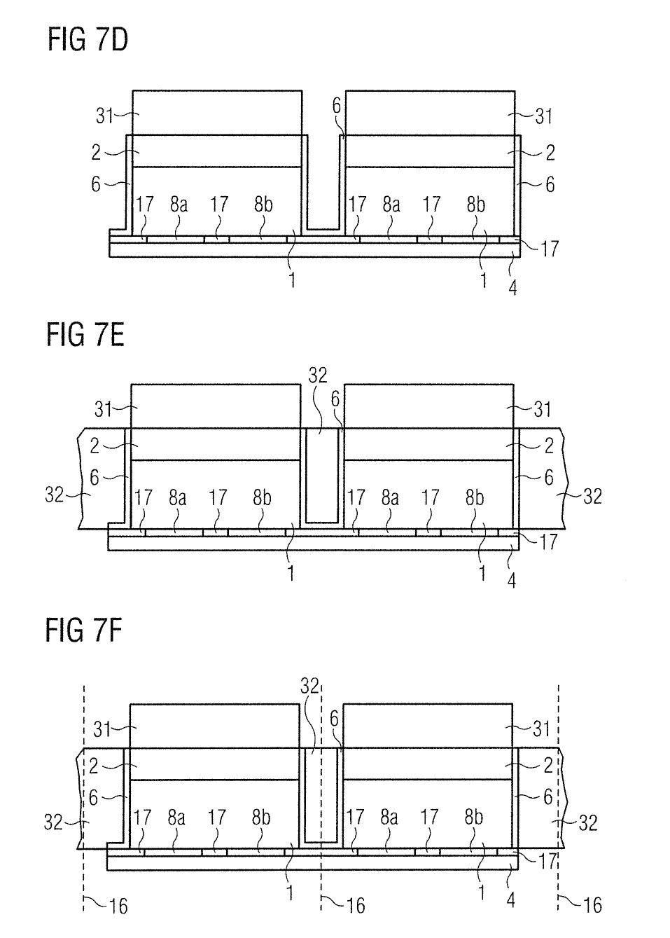

FIGS. 7A to 7F show a method of producing an optoelectronic component according to an example. FIG. 7A shows provision of a carrier 4. In particular, the carrier 4 is a reversible carrier.

Subsequently, a semiconductor chip 1 is applied, shown here as two semiconductor chips 1 by way of example. In particular, the semiconductor chips 1 are applied on to the reversible carrier with their rear-side contacts 8a, 8b.

Subsequently, an insulating material 17 can be dispersed as a plastic material layer (FIG. 7B). Neighboring semiconductor chips 1 are thereby electrically-insulated from one another.

FIG. 7C shows application of a converter element 2 and of a cover element 31 in each case on a semiconductor chip 1. The cover element 31 can be of glass or silicon dioxide, for example.

FIG. 7D subsequently shows application of a seed layer 6. The seed layer 6 is in particular applied on to the side surfaces 12 of the semiconductor chip 1 and on to the side surfaces 21 of the converter element 2. The seed layer 6 in particular comprises a metal. In particular, the seed layer 6 is formed of silver. The seed layer 6 is applied by sputtering. In particular, application takes places by a photo-technique.

After that, application of the side element 32 can be effected (FIG. 7E). The side element 32 is applied between neighboring semiconductor chips 1. The side element 32 is in particular arranged in direct contact to the seed layer 6. The side element 32 can be of copper or nickel.

Subsequently, as shown in FIG. 7F, the components 100 can be singulated 16. This can be effected mechanically or lithographically.

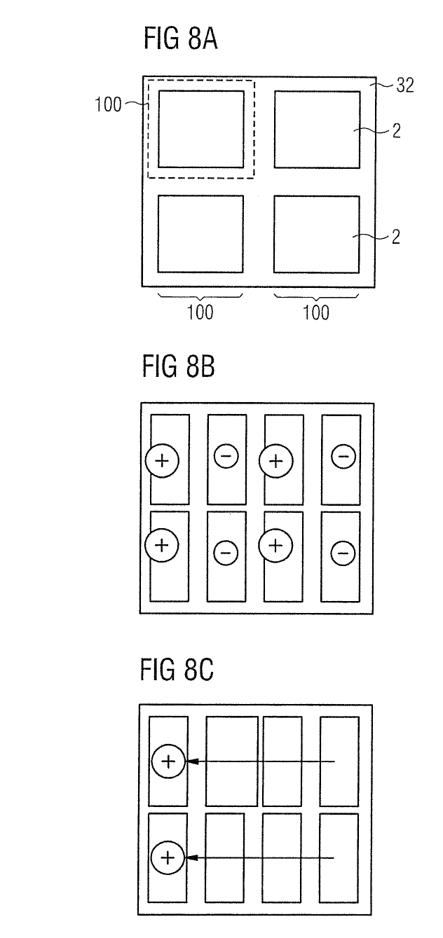

FIGS. 8A to 8C each show an assembly of optoelectronic components. FIG. 8A shows the top view of an assembly of optoelectronic components. Four optoelectronic components 100 are illustrated. However, more than four optoelectronic components 100 can form an assembly. The optoelectronic components are in particular formed as so-called arrays. The assembly of neighboring optoelectronic components in particular comprises a common side element 32. In other words, neighboring components share a side element 32. The side element 32 can be formed of a metal, for example. Mechanical stability can be increased thereby, and the side element 32 can be used as a heat sink for the respective semiconductor chips 1 and converter elements 2. The side element 32 can be adjusted accordingly, depending on the thermal requirements. If the converter element 2 has a high thermal conductivity, the size of the converter element 2 can be selected to be comparatively large compared to the dimensions of the side element 32. If the thermal conductivity of the converter element 2 is rather low, the dimensions of the side element 32 can be selected relatively large for the purpose of an improved heat dissipation. The cover element 31 can additionally comprise diffuse or optical elements to increase the out-coupling of light.

FIG. 8B shows the assembly of FIG. 8A from below.

In particular, the assembly is connected in series, as shown in FIG. 8C.

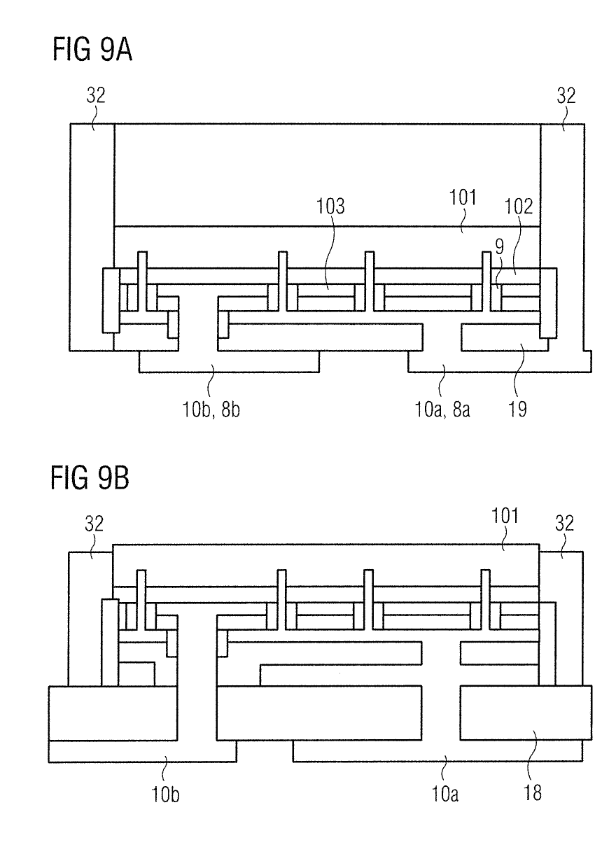

FIG. 9A shows a schematic side view of an optoelectronic component according to an example. In particular, FIG. 9A shows a configuration of a semiconductor chip. The semiconductor chip 1 in particular comprises electrical contacts 10a and 10b. In particular, the electrical contact 10a is in direct contact with the side element 32. The semiconductor chip 1 is in particular formed such that it comprises through-connections to the corresponding semiconductor layers. The component 100 comprises a combo mirror 19. In addition, the side element 32 can be arranged in direct contact to the semiconductor chip 2 in the configuration of the semiconductor chip 1 (not shown here).

In particular, the electric contact 10b contacts the p-type semiconductor layer 103 as a p-contact. As an n-contact, the electric contact 10a in particular contacts the n-type semiconductor layer 101. The n-contact in particular comprises through-bores to the n-type semiconductor layer 101. The semiconductor chip 1 of FIG. 9A comprises rear-side contacts 8a, 8b, which are both located on the same side and are electrically connected to the respective p-/n- contacts 10a, 10b and are formed of the same material.

FIG. 9b shows a different configuration of a semiconductor chip 1. In particular, the component of FIG. 9B differs from the component of FIG. 9A in that the component of FIG. 9B additionally comprises a submount 18. The submount 18+can be of silicon or ceramics, for example.

The examples described in conjunction with the Figures and the features thereof can also be combined with one another according to further examples, even if such combinations are not explicitly disclosed in conjunction with the Figures. Furthermore, the examples descried in conjunction with the Figures can comprise additional or alternative features according to the general part of the description.

Our components, assemblies and methods are not limited to the examples by the description of the examples. This disclosure rather comprises any new feature as well as any combination of features, which in particular includes any combination of features in the appended claims, even if the feature or combination is per se not explicitly indicated in the claims or the examples.

This application claims priority of DE 10 2015 111 910.2, the subject matter of which is incorporated herein by reference.

1-15. (canceled)

16. An optoelectronic component comprising:
a semiconductor chip configured to emit radiation at least via a main radiation surface,
a converter element arranged in a beam path of the semiconductor chip,
an encapsulating element comprising a cover element and a side element and forming at least a seal for the converter element against environmental influences,
wherein the cover element is arranged above the converter element and the side element, in the cross-section, is arranged laterally to the semiconductor chip and converter element and surrounds the semiconductor chip,
the side element and the cover element are in direct contact at least in regions, and
the side element comprises at least one metal and is in direct contact with the converter element in the lateral direction.

17. The optoelectronic component according to claim 16, wherein the side element consists of at least one galvanic metal and the cover element comprises a material different from the side element and is transparent to the radiation emitted by the semiconductor chip, wherein the side element has a thickness of smaller than 50 μm.

18. The optoelectronic component according to claim 16, wherein the converter element comprises quantum dots.

19. The optoelectronic component according to claim 16, wherein the side element is formed as an electrical connection contact of the semiconductor chip.

20. The optoelectronic component according to claim 16, wherein at least the side element is arranged on a carrier so that the side element is configured as a heat sink for the converter element and/or the semiconductor chip, and at least degradation of the converter element is prevented.

21. The optoelectronic component according to claim 16, wherein the side element is formed to be reflective.

22. The optoelectronic component according to claim 16, further comprising a seed layer that completely directly covers the side surfaces of the converter element and directly covers the side surfaces of the semiconductor chip at least in regions, wherein the side element is laterally directly downstream of the seed layer.

23. The optoelectronic component according to claim 16, wherein the seed layer is formed to be reflective.

24. The optoelectronic component according to claim 22, wherein the semiconductor chip and the converter element each comprise side surfaces covered directly by the seed layer in a form-fit manner.

25. The optoelectronic component according to claim 16, wherein the side element comprises copper or nickel.

26. An assembly of the optoelectronic component according to claim 16, wherein neighboring optoelectronic components have a common side element.

27. The assembly according to claim 26, wherein at least neighboring optoelectronic components are connected in series.

28. A method of producing the optoelectronic component according to claim 16 comprising:
A) providing a cover element of an encapsulating element,
B) applying a converter element on to the cover element of the encapsulating element, wherein the converter element comprises side surfaces,
C) applying at least one semiconductor chip on to the converter element, wherein the semiconductor chip is configured to emit radiation at least via a main radiation surface and comprises side surfaces, and
D) applying a side element on to the side surfaces of the semiconductor chip and on to the side surfaces of the converter element so that, in the cross-section, the side element is arranged laterally to the semiconductor chip and converter element and directly surrounds at least the semiconductor chip, wherein the side element and the cover element directly contact one another at least in some regions and form a seal for the converter element against environmental influences, and
the side element comprises at least one metal and is in direct contact with the converter element in the lateral direction.

29. The method according to claim 28, wherein the side element is produced galvanically in step D).

30. The method according to claim 28, wherein before step D), a seed layer is applied completely on to the side surfaces of the converter element and at least in some regions on to the side surfaces of the semiconductor chip, wherein the seed layer is formed to be reflective.
